(19) United States
(12) Patent Application Publication
(10) Pub. No.: US 2007/0001188 A1
(43) Pub. Date: Jan. 4, 2007

(54) Semiconductor device for emitting light and method for fabricating the same

(76) Inventor: Kyeong-Cheol Lee, Jeonju-city (KR)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 10/574,743

(22) PCT Filed: Oct. 26, 2004
(86) PCT No.: PCT/KR04/02722

§ 371 Date: Apr. 6, 2006

(30) Foreign Application Priority Data
Sep. 10, 2004 (KR) 10-2004-0072405

(51) Int. Cl. H01L 33/00; H01L 21/00

(52) U.S. Cl. 257/99; 257/100; 438/22; 257/E33.059

(57) ABSTRACT

A semiconductor light emitting device includes a package (5) having two or more terminals, two or more semiconductor devices (1,2) mounted in the package to emit lights each having a predetermined wavelength, and a molding unit (3) mixed with a phosphor. The phosphor is excited by the lights emitted from the semiconductor devices to emit light having a wavelength different from those of the lights emitted from the semiconductor devices.

### BACKGROUND OF THE INVENTION

a) Field of the Invention

The present invention relates to a semiconductor device for emitting light and a method for making the same, and more particularly, to a semiconductor light emitting device that can emit light having a desired wavelength by mounting semiconductor devices having different wavelengths from each other and exciting phosphors using lights emitted from the semiconductor devices to emit lights having different wavelengths from those of lights emitted from the semiconductor devices, and a method for making the same.

b) Description of the Related Art

Light emitting diodes (LEDs) are kinds of semiconductor devices that are designed to realize red, green, and yellow light. In recent years, a blue LED has been developed to realize white light. That is, since the three primary colors (red, green, and blue colors) can be emitted by the red, green, and blue LEDs, white light can be realized.

A white LED is designed to emit white light by applying yellow phosphor to a blue chip. However, since such a white LED has a weak red color, its color rendering index (CRI) is deteriorated.

In order to solve the above problem, a method in which blue, red, and green phosphors are deposited on an ultraviolet (UV) chip generating a ultraviolet wavelength to realize the white light has been studied. However, this method cannot be commercialized due to efficiency and reliability problems of the red phosphor and the lower power of the UV chip.

Alternatively, the white light has been realized using red, blue, and green chips. However, in this case, a variety of problems such as light intensity of the chips, maintaining balance, price, power consumption, and driving factors are encountered.

### SUMMARY OF THE INVENTION

Therefore, the present invention has been made in an effort to solve the above-described problems.

It is an objective of the present invention to provide a semiconductor light emitting device and a method for making the same, which can emit light having a desired wavelength by mounting semiconductor devices having different wavelengths from each other and exciting phosphors using the lights emitted from the semiconductor devices to emit lights having different wavelengths from those of lights emitted from the semiconductor devices.

It is another objective of the present invention to provide a semiconductor light emitting device and a method for making the same, which can represent a wide range of color, provide an improved CRI₁ easily adjust white color hues by current conversion of blue and red colors, maximize optical efficiency, and improve the productivity and quality of the products.

### BRIEF DESCRIPTION OF THE DRAWINGS

The accompanying drawings, which are included to provide a further understanding of the invention and are incorporated in and constitute a part of this application, illustrate embodiment(s) of the invention, and together with the description serve to explain the principle of the invention. In the drawings:

FIGS. 1a and 1b are respectively plane and side views of a side light emitting diode package as a semiconductor light emitting device according to a preferred embodiment of the present invention;

FIGS. 2a and 2b are respectively plane and side views of a top view LED package as a semiconductor light emitting device according to another preferred embodiment of the present invention;

FIGS. 3a and 3b are plane and side views of a side emitting type of LED package according to another preferred embodiment of the present invention;

FIG. 4 is a side view of a vertical LED package as a semiconductor light emitting device according to another embodiment of the present invention;

FIG. 5a is a graph illustrating spectrums of a prior semiconductor light emitting device and a semiconductor light emitting device of the present invention;

FIG. 5b is a graph illustrating spectrums after passing through an LCD color filter;

FIG. 5c is a graph illustrating a spectrum before and after a green phosphor is deposited; and

FIG. 6 is a flowchart illustrating a process for fabricating a semiconductor light emitting device according to a preferred embodiment of the present invention.

### SUMMARY OF THE INVENTION

It is an objective of the present invention to provide a semiconductor light emitting device and a method for making the same, which can emit a variety of colors including white light by mixing lights emitted from semiconductor devices with lights emitted from phosphors, wherein the lights emitted from the semiconductor devices have wavelengths different from each other and the lights emitted from the phosphors have wavelengths different from those of the lights emitted from the semiconductor devices.

To achieve the objectives, the present invention provides a semiconductor light emitting device comprising a package having two or more terminals; two or more semiconductor devices mounted in the package to emit lights, each having a predetermined wavelength; and a molding unit mixed with a phosphor that is excited by the lights emitted from the semiconductor devices to emit light having a wavelength different from those of the lights emitted from the semiconductor devices.

According to another aspect of the present invention, there is provided a method for making a semiconductor light emitting device comprising the steps of mounting two or more semiconductor devices on a package having two or more terminals; electrically connecting the semiconductor devices to each other using a conductive wire; and forming a molding unit by mixing a phosphor with a transparent molding material, the phosphor being excited by the lights emitted from the semiconductor devices to emit light having wavelengths different from those of the lights emitted from the semiconductor devices.

### DETAILED DESCRIPTION OF PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

The inventive semiconductor light emitting device can be employed in a variety of applications. However, the embodiments will be described as a case when it is applied to a variety of LEDs.

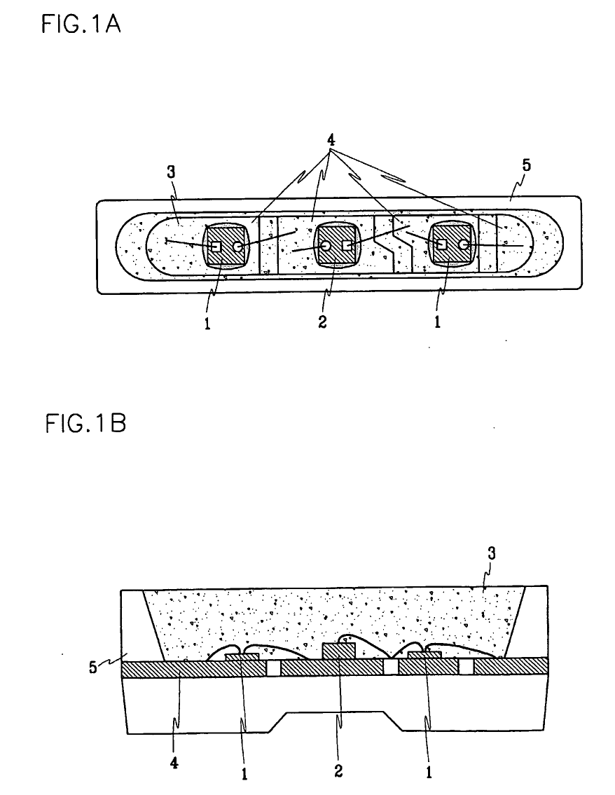

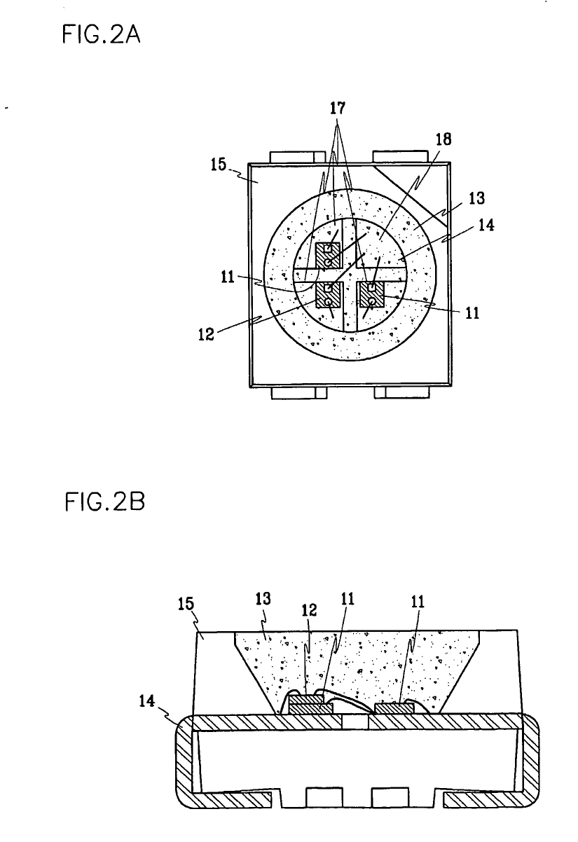

As shown in FIGS. 1a through 2b, an LED is exemplified as a semiconductor light emitting device according to a preferred embodiment of the present invention.

Referring first to FIGS. 1a and 1b, the inventive LED includes a package 5 having two or more terminals, two or more semiconductor devices 1 and 2 mounted in the package 5, and a molding unit 3 mixed with phosphors emitting lights having a wavelength different from lights emitted from the semiconductor devices 1 and 2.

The semiconductor devices 1 and 2 are comprised of device groups that can emit lights having wavelengths different from each other in a range of visible rays, preferably two blue chips 1 and one red chip 2.

The two blue chips 1 and the red chip 2 are electrically connected to each other by a conductive wire.

When electric power is applied, the chips 1 and 2 emit lights each having a predetermined wavelength.

The blue chips 1 have a peak wavelength of about 430-480 nm. The red chip 2 has a peak wavelength of about 610-700 nm.

Although the blue chips 1 and the red chip 2 are connected in a series connection in the drawing, the present invention is not limited to this. That is, the chips 1 and 2 can be connected in a parallel connection.

The chips 1 and 2 are enclosed by the molding unit 3 mixed with the phosphors.

At this point, the molding unit 3 is formed by mixing molding material with phosphor material at a predetermined ratio. That is, the molding material is formed of transparent material such as epoxy resin, urea resin, and silicone. The molding unit 3 protects the semiconductor devices and the conductive wire, and also functions as a lens that radiates lights emitted from the semiconductor devices 1 and 2. The phosphor may include a variety of phosphors that can be excited by the semiconductor devices 1 and 2 to emit lights having wavelengths different from those of lights emitted from the semiconductor devices 1 and 2.

Preferably, the phosphor includes a green phosphor. The green phosphor has an excitation wavelength of about 200-550 nm and an emission peak wavelength of about 500-570 nm.

The lights emitted from the semiconductor devices 1 and 2 excite the phosphor to emit lights having a variety of colors.

For example, in order to emit white light, electric power is applied to the blue and red chips 1 and 2 so the blue chips 1 emit blue light having a blue wavelength and the red chip 2 emits red light having a red wavelength.

When the blue and red lights reach the phosphor, a portion of the blue wavelength excites the green phosphor to generate a green wavelength, and another portion of the blue wavelength is emitted to an external side. The red wavelength is also emitted to the external side. As a result, the white light having three primary colors (blue, red, and green colors) can be realized.

Although a case where the blue and red chips are mounted and the green phosphor is provided is described above, the present invention is not limited to this case.

A combination of blue and green chips and a red phosphor can be possible. A combination of red and green chips and a blue phosphor can be also possible.

Alternatively, blue, red, and green chips are mounted and an appropriate phosphor can be provided. A variety of combinations can be selected according to the products.

The semiconductor devices 1 and 2 may include at least one UV device emitting light in a wavelength range of ultraviolet rays.

As described above, the light realized by the inventive semiconductor light emitting device has a wide range of color having blue, green, and red wavelengths and improved color reproduction.

FIGS. 2a and 2b show another preferred embodiment of the present invention. In this embodiment, the present invention is applied to a PLCC type of package.

That is, two blue chips 11 and one red chip 12 are mounted, and a mixture of a green phosphor and epoxy is filled in a package 5.

At this point, four pads 17 and 18 are provided on an electrode terminal 14. The four pads 17 and 18 are arranged in a circular direction. The two blue chips 11 and the red chip 12 are mounted on some of the pads 17, and wires extending from the chips 11 and 12 are connected to one pad 18 on which the chips 11 and 12 are not mounted.

Accordingly, when electric power is applied, the device of this embodiment can realize a variety of light colors by an identical principle as that of the device depicted in FIGS. 1a and 1b.

In addition, as in the forgoing embodiment, at least two semiconductor devices 11 and 12 can be formed in a variety of combinations. By providing an appropriate phosphor, other colors can be realized in addition to the white light.

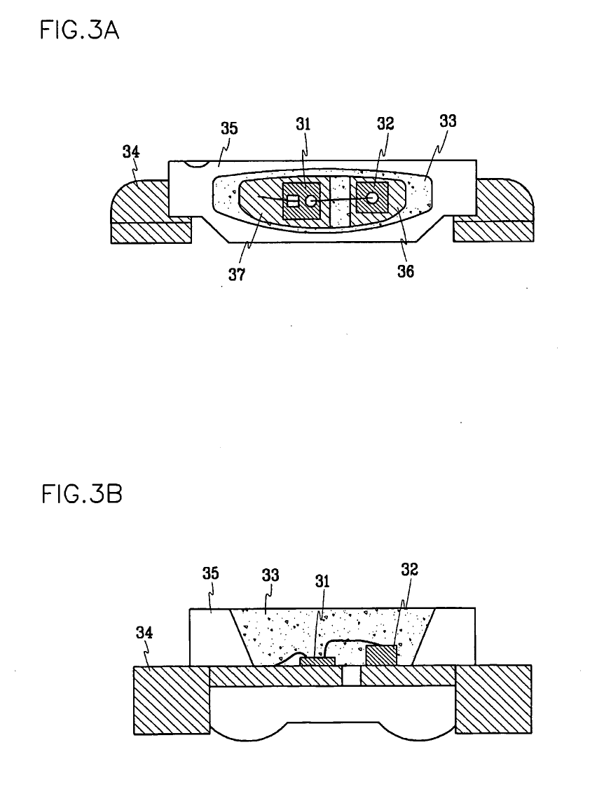

FIGS. 3a and 3b show another preferred embodiment of the present invention. In this embodiment, the present invention is applied to a side view type of package.

As in the forgoing embodiments, one blue chip 31 and one red chip 32 are mounted, and a mixture of a green phosphor and epoxy is filled in an injection plastic 35 to form a molding unit 33.

In this embodiment, a pair of pads 36 and 37 are provided, and the blue and red chips 31 and 32 are respectively mounted on the pads 36 and 37. The blue and red chips 31 and 32 are connected to each other by a wire.

Accordingly, when electric power is applied, the device of this embodiment can realize a variety of light colors according by an identical principle as that of the device depicted in FIGS. 1a and 1b.

In addition, as in the forgoing embodiment, at least two semiconductor devices 11 and 12 can be formed in a variety of combinations. By providing an appropriate phosphor, other colors can be realized in addition to the white light.

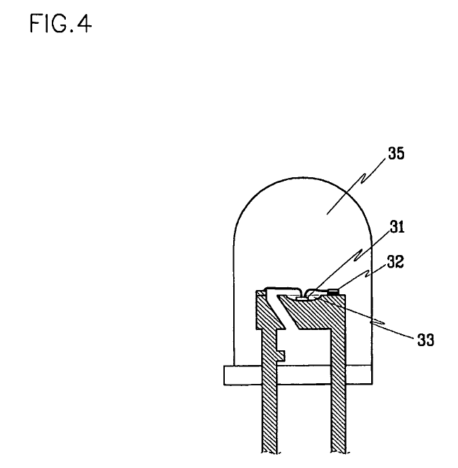

FIG. 4 shows another preferred embodiment of the present invention. In this embodiment, the present invention is applied to a vertical LED.

That is, as in the forgoing embodiments, one blue chip 31 and one red chip 32 are mounted, and the chips 31 and 32 are enclosed by a molding unit 35.

Accordingly, when electric power is applied, the device of this embodiment can realize a variety of light colors according to an identical principle as that of the device depicted in FIGS. 1a and 1b.

In addition, as in the foregoing embodiment, at least two semiconductor devices 11 and 12 can be formed in a variety of combinations. By providing an appropriate phosphor, other colors can be realized in addition to the white light.

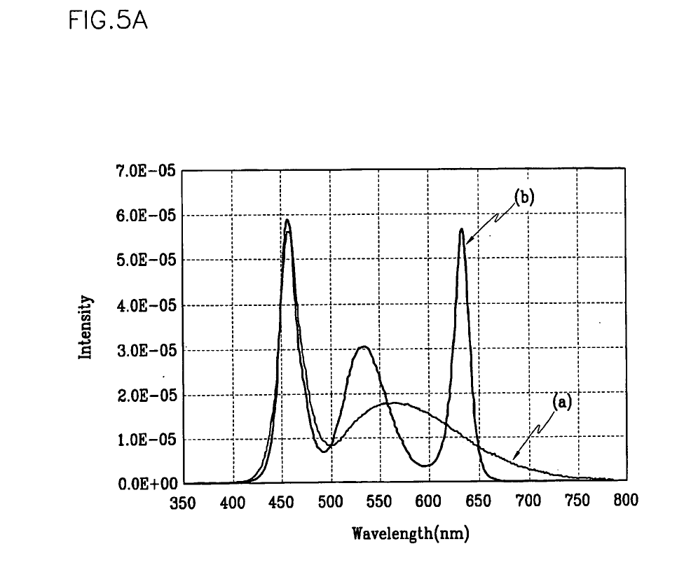

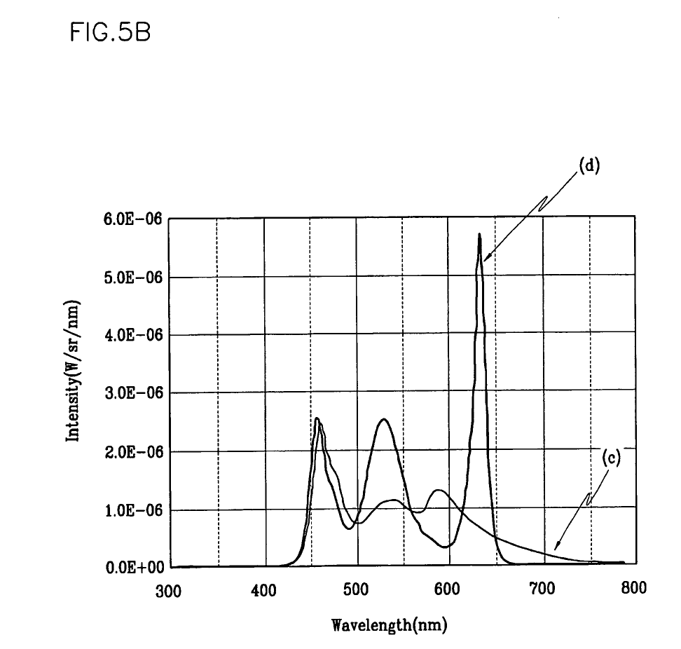

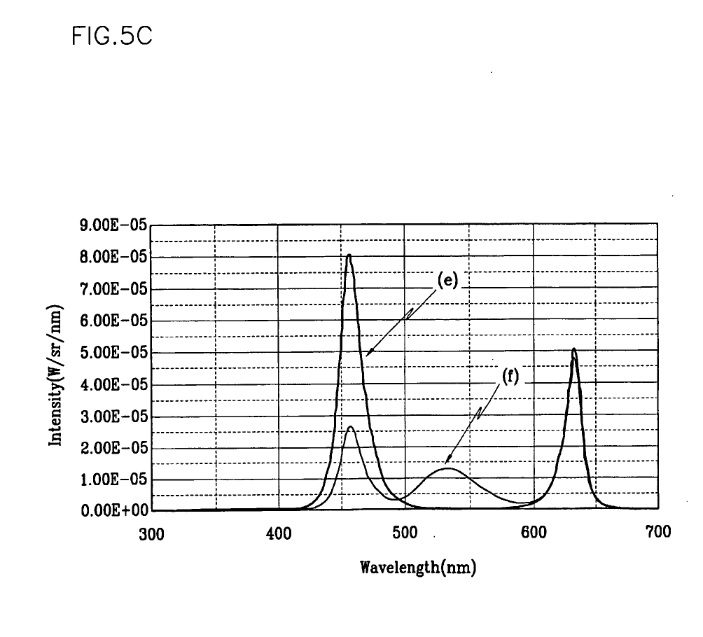

FIGS. 5a and 5b are graphs illustrating spectrums of a prior semiconductor light emitting device and a semiconductor light emitting device of the present invention.

In the graph, the curve (a) is a case where the white light is realized by providing a blue chip and depositing a yellow phosphor, and the curve (b) is a case where the white light is realized by depositing a green phosphor on blue and red chips.

As shown in the graph, the curve (a) has a blue peak wavelength, a yellow peak wavelength, and a partly red wavelength.

Conversely, the curve (b) has blue, green, and red peak wavelengths that are uniformly formed.

As shown in FIG. 5b, the curve (c) shows that when the spectrum of the curve (a) depicted in FIG. 5a passes through an LCD color filter, it has low optical efficiency and low color purity with respect to blue, green, and red peak wavelengths.

Conversely, the curve (d) shows that when the spectrum of the curve (b) depicted in FIG. 5a passes through an LCD color filter, it has high optical efficiency and high color purity with respect to blue, green, and red peak wavelengths.

FIG. 5c shows a graph comparing blue and red spectrums before and after they pass through the green phosphor illustrating spectrums obtained before a green phosphor is deposited.

As shown in the graph, the curve (e) represents a spectrum of a light emitting wavelength of each of the blue and red chips, and the curve (f) represents a spectrum after the light emitting wavelength depicted in the curve (e) passes through the green phosphor. A portion of the blue wavelength excites the green phosphor to generate a green wavelength, and a portion of the blue wavelength and the red wavelength are emitted as they are, thereby providing blue, green, and red peak wavelengths.

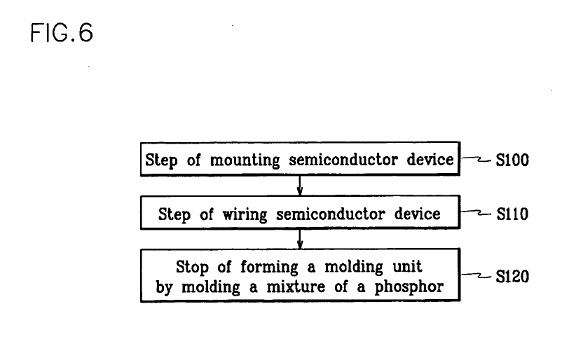

FIG. 6 shows a method for fabricating a semiconductor light emitting device according to a preferred embodiment of the present invention. The method will be described hereinafter with reference to FIGS. 1 and 6.

The blue and red chips 1 and 2 are first mounted on the semiconductor package 4 having two or more terminals (S100).

In step S100, the blue and red chips 1 and 2 may be arranged in a variety of ways. That is, as described above, the four pads are arranged in series, and the two blue chips 1 and one red chip 2 are mounted on the pads and connected to each other in series. Alternatively, the blue and red chips may be arranged in a circular direction and be connected to each other in parallel.

Alternatively, one blue chip and one red chip may be respectively mounted on a pair of pads. Alternatively, blue and red chips may be respectively arranged on vertical types of LEDs.

At this point, the blue chip has a peak wavelength of about 430-480 nm, and the red chip has a peak wavelength of about 610-700 nm.

After the arrangement of the blue and red chips is finished, the molding unit 3 is formed (S120). That is, the green phosphor and the transparent molding material are mixed with each other at a predetermined ratio and molded.

At this point, the green phosphor has an excitation wavelength of about 200-550 nm and a light emitting peak wavelength of about 500-570 nm so that it can be excited by a blue wavelength.

When the lights emitted from the blue and red chips 1 and 2 reach the molding unit 3, the blue wavelength excites the green phosphor to generate a green wavelength and a portion of the blue wavelength and red wavelength are emitted to an external side, thereby realizing the white light.

The semiconductor light emitting device has advantages as follows.

First, since the phosphors are excited by lights emitted from the semiconductor devices, which have wavelengths different from each other, lights having wavelengths different from those of the lights emitted from the semiconductor devices can be radiated.

Second, the white LED realized by deposing a yellow phosphor to a blue chip has a weak red color wavelength and a narrow color reproduction. However, when the present invention is applied, blue, green, and red wavelengths can be uniformly formed, widening the color reproduction range.

Particularly, when a conventional white LEDs using a blue chip and yellow phosphor is applied, the color reproduction rate is only 40% of the standard of NTSC (national television system committee). However, when the present invention is applied, the color reproduction rate can be more than 100% of the standard of NTSC. When the present invention is applied to a backlight of the LCD, the light loss caused by the color filter can be minimized.

Third, when the red, blue, and green chips are used to realize the white light, it is difficult to maintain the color balance and the driving circuit is required since the brightness and the wavelength of each chip should be matched. Therefore, the power consumption is increased and the manufacturing cost is increased. However, in the present invention, since the green chip is omitted and the green phosphor is used, the white light can be obtained by adjusting only the brightness and wavelength of the red light. In this case, the power consumption can be reduced and the light efficiency can be improved.

Fourth, the method for realizing the white light by using the UV LED chip and the blue, green and red phosphors has not been commercialized due to the low light efficiency of the UV LED chip and the reliability and efficiency problems of the red phosphor. However, in the present invention, since the blue and red chips are applied and the red phosphor is omitted, the light efficiency and the reliability can be improved.

Fifth, by connecting the chips in series, the pure white light can be realized using only two terminals, thereby making it possible to simplify a driving circuit.

Sixth, since the chips may be connected to each other by a series or parallel combination, the color balance can be maintained, thereby realizing a desired color sense.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A semiconductor light emitting device comprising:
a package having two or more terminals;
two or more semiconductor devices mounted in the package to emit lights, each having a predetermined wavelength; and
a molding unit mixed with a phosphor that is excited by the lights emitted from the semiconductor devices to emit light having a wavelength different from those of the lights emitted from the semiconductor devices.

2. The semiconductor light emitting device of claim 1, wherein the semiconductor devices include two or more semiconductor device groups emitting lights having a wavelength in a different visible ray range from each.

3. The semiconductor light emitting device of any one of claims 1 and 2, wherein the semiconductor devices includes one or more devices emitting blue light and one or more devices emitting red light.

4. The semiconductor light emitting device of claim 3, wherein the semiconductor device emitting blue light has a peak wavelength of about 430-480 nm.

5. The semiconductor light emitting device of claim 3, wherein the semiconductor device emitting the red light has a peak wavelength of about 610-700 nm.

6. The semiconductor light emitting device of claim 1, wherein at least one of the semiconductor devices emits light in an ultraviolet ray range.

7. The semiconductor light emitting device of claim 1, wherein the molding unit is formed of a mixture of phosphor and a molding material, the phosphor being designed to emit green light when it is excited by the light emitted from the semiconductor device.

8. The semiconductor light emitting device of claim 7, wherein the phosphor has an excitation wavelength of about 200 -550 nm and an emitting wavelength of about 500-570 nm.

9. The semiconductor light emitting device of claim 1, wherein the molding unit is formed of a mixture of phosphor and a molding material, the phosphor being designed to emit red light when it is excited by the light emitted from the semiconductor device.

10. The semiconductor light emitting device of claim 1, wherein at least one of the semiconductor devices emits light having a similar color to that of the light emitted from the phosphor.

11. The semiconductor light emitting device of claim 1, wherein the semiconductor devices include one or more red light emitting devices and one or more blue light emitting devices, and the phosphor is designed to emit green light when it is excited by the light emitted from the semiconductor devices, thus the semiconductor light emitting device radiates white light.

12. The semiconductor light emitting device of claim 11, further comprising one or more green light emitting devices.

13. The semiconductor light emitting device of claim 1, wherein the semiconductor devices include one or more blue light emitting devices and one or more green light emitting devices, and the phosphor is designed to emit red light when it is excited by the light emitted from the semiconductor devices, thus the semiconductor light emitting device radiates white light.

14. The semiconductor light emitting device of claim 13, further comprising one or more red light emitting devices.

15. The semiconductor light emitting device of claim 1, wherein the semiconductor device include an LED.

16. The semiconductor light emitting device of claim 1, wherein the semiconductor devices are connected to each other in series, in parallel, or in series-parallel.

17. A method for making a semiconductor light emitting device, comprising the steps of:
mounting two or more semiconductor devices on a package having two or more terminals;
electrically connecting the semiconductor devices to each other using a conductive wire; and
forming a molding unit by molding a mixture of a phosphor and a transparent molding material, the phosphor being excited by the lights emitted from the semiconductor devices to emit light having a wavelength different from those of the lights emitted from the semiconductor devices.

18. The method of claim 17, wherein the transparent molding material is selected from the group consisting of epoxy resin, urea resin, and silicone.

19. The method of claim 17, wherein the semiconductor devices comprise a blue chip having a peak wavelength of about 430-480 nm and a red chip having a peak wavelength of about 610-700 nm, and the phosphor has an excitation wavelength of about 200-550 nm and an emitting wavelength of about 500-570 nm.
